(19) United States
(12) Patent Application Publication
(10) Pub. No.: US 2026/0068438 A1
(43) Pub. Date: Mar. 5, 2026

(54) DISPLAY DEVICE, METHOD OF FABRICATING THE SAME, AND ELECTRONIC DEVICE INCLUDING THE SAME

(71) Applicant: Samsung Display Co., LTD., Yongin-si (KR)

(72) Inventors: Soo Youn KIM, Yongin-si (KR); Hee Jun YANG, Yongin-si (KR); Soo Min OH, Yongin-si (KR); Seung Gun CHAE, Yongin-si (KR)

(21) Appl. No.: 19/216,049

(22) Filed: May 22, 2025

(30) Foreign Application Priority Data
Sep. 4, 2024 (KR) 10-2024-0119842

(51) Int. Cl. H10K 59/122; G02B 27/01; H10K 59/12; H10K 59/123; H10K 59/80; H10K 71/60; H10K 77/10; H10K 102/00

(52) U.S. Cl. CPC H10K 59/122; G02B 27/0172; H10K 59/1201; H10K 59/123; H10K 59/80515; H10K 71/60; H10K 77/111; G02B 2027/0178; H10K 2102/311

(57) ABSTRACT

A display device includes a substrate including an emission area and a non-emission area surrounding the emission area; a bank structure located on the emission area of the substrate and comprising a tip protruding toward the non-emission area; an anode contact hole penetrating the bank structure; an anode located on the bank structure and electrically connected to a transistor located on the substrate through the anode contact hole; a pixel defining layer located on the anode; and a light emitting layer located on the pixel defining layer, wherein the light emitting layer is spaced apart from the anode with the pixel defining layer therebetween in a portion overlapping the anode contact hole in a plan view and contacts the anode in a portion not overlapping the anode contact hole in the plan view.

This application claims priority to Korean Patent Application No. 10-2024-0119842, filed on Sep. 4, 2024, and all the benefits accruing therefrom under 35 U.S. C. § 119, the content of which in its entirety is herein incorporated by reference.

### BACKGROUND

### 1. Field

The present disclosure relates to a display device and a method of fabricating the same.

### 2. Description of the Related Art

As the information society develops, demands for display devices for displaying images are increasing in various forms. For example, display devices are applied to various electronic devices such as smartphones, digital cameras, notebook computers, navigation devices, and smart televisions. The display devices may be flat panel display devices such as liquid crystal display devices, field emission display devices, and organic light emitting display devices. Among these flat panel display devices, a light emitting display device includes a light emitting element that enables each pixel of a display panel to emit light by itself. Thus, the light emitting display device can display an image without a backlight unit that provides light to the display panel.

### SUMMARY

An aspect of the present disclosure is to provide a display device capable of providing a high-resolution image and a method of fabricating the display device.

Another aspect of the present disclosure is to solve a short-circuit between an anode and a cathode.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

In an embodiment of the disclosure, a display device includes a substrate including an emission area and a non-emission area surrounding the emission area; a bank structure located on the emission area of the substrate and including a tip protruding toward the non-emission area; an anode contact hole penetrating the bank structure; an anode located on the bank structure and electrically connected to a transistor located on the substrate through the anode contact hole; a pixel defining layer located on the anode; and a light emitting layer located on the pixel defining layer, where the light emitting layer is spaced apart from the anode with the pixel defining layer therebetween in a portion overlapping the anode contact hole in a plan view and contacts the anode in a portion not overlapping the anode contact hole in the plan view.

In an embodiment, the bank structure may include a first bank layer; a second bank layer located on the first bank layer; and a third bank layer having the tip which protrudes toward the non-emission area more than a first side surface of the second bank layer which faces the non-emission area.

In an embodiment, the second bank layer and the third bank layer may surround the anode contact hole.

In an embodiment, a shape of the bank structure facing the anode contact hole and a shape of the bank structure facing the non-emission area may be different from each other.

In an embodiment, a second side surface of the second bank layer may be in line with a third side surface of the third bank layer which face the anode contact hole.

In an embodiment, the pixel defining layer may include a first pixel defining layer located between the bank structure and the anode; a second pixel defining layer covering an edge of the anode and overlapping the emission area to define a first opening; and a third pixel defining layer overlapping the anode contact hole and located under the light emitting layer and on the anode.

In an embodiment, a second opening may be defined between the third pixel defining layer and the second pixel defining layer in a direction parallel to a major surface of the substrate.

In an embodiment, the light emitting layer may contact the anode in a portion overlapping the second opening in the plan view.

In an embodiment, the first pixel defining layer and the second pixel defining layer may overlap the tip of the third bank layer in a direction perpendicular to the major surface of the substrate.

In an embodiment, the second pixel defining layer and the third pixel defining layer may include the same material.

In an embodiment, the display may further include a first cathode located on the light emitting layer; a first auxiliary electrode located on the first cathode and contacting the first side surface of the second bank layer; and a first element inorganic layer located on the first auxiliary electrode.

In an embodiment, the first cathode may do not contact the first side surface of the second bank layer and may be electrically connected to the second bank layer through the first auxiliary electrode.

In an embodiment, the first auxiliary electrode may be spaced apart from the first bank layer with a cavity therebetween in the direction perpendicular to the major surface of the substrate.

In an embodiment, the display may further include a second cathode spaced apart from the first cathode in a portion overlapping the non-emission area; a second auxiliary electrode located on the second cathode and spaced apart from the first auxiliary electrode; and a second element inorganic layer located on the second auxiliary electrode and spaced apart from the first element inorganic layer, where the first auxiliary electrode and the second auxiliary electrode may be electrically connected.

In an embodiment, the display may further include a connection electrode located between the substrate and the bank structure and electrically connected to the transistor; and a via-layer covering the connection electrode, where the anode contact hole penetrates the via-layer, and the anode is electrically connected to the transistor through the connection electrode.

In an embodiment, the second pixel defining layer may include an inorganic material, and the third pixel defining layer includes an organic material.

In an embodiment, a method of fabricating a display device includes forming a bank structure having an undercut shape on an emission area of the substrate; forming an anode contact hole which penetrates the bank structure and exposes a connection electrode; forming an anode which is located on the bank structure and contacts the connection electrode through the anode contact hole; and forming a pixel defining layer on the anode and forming a light emitting layer and a cathode on the pixel defining layer, where the anode and the light emitting layer are separated by the pixel defining layer in a portion overlapping the anode contact hole.

In an embodiment, the bank structure may include a first bank layer, a second bank layer and a third bank layer, the second bank layer and the third bank layer include different metal materials from each other, and in the forming of the anode contact hole, the anode contact hole is formed by simultaneously removing a portion of each of the first bank layer, the second bank layer and the third bank layer.

In an embodiment, in the forming of the light emitting layer and the cathode, the light emitting layer and the cathode may be formed by a deposition process and an etching process without a fine metal mask.

In an embodiment, an electronic device includes at least one display device including a substrate which includes an emission area and a non-emission area; a display device housing in which the at least one display device is accommodated; and an optical member for enlarging an image displayed by the at least one display device or converting an optical path, where the at least one display device includes a bank structure located on the emission area of the substrate and including a tip protruding toward the non-emission area; an anode contact hole penetrating the bank structure; an anode located on the bank structure and electrically connected to a transistor located on the substrate through the anode contact hole; a pixel defining layer located on the anode; and a light emitting layer located on the pixel defining layer, and the light emitting layer is spaced apart from the anode with the pixel defining layer therebetween in a portion overlapping the anode contact hole in a plan view and contacts the anode in a portion not overlapping the anode contact hole in the plan view.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view of a head mounted electronic device according to an embodiment;

FIG. 2 is an exploded perspective view of an example of the head mounted electronic device of FIG. 1;

FIG. 3 is a perspective view of a head mounted electronic device according to an embodiment;

FIG. 4 is a perspective view of a display device according to an embodiment;

FIG. 5 is a cross-sectional view of the display device according to the embodiment;

FIG. 6 is a plan view of a display layer of the display device according to the embodiment;

FIG. 7 is a layout view illustrating the arrangement of a plurality of pixels in a display area of FIG. 6;

FIG. 8 is another example and a layout view illustrating the arrangement of a plurality of pixels in the display area of FIG. 6;

FIG. 9 is a cross-sectional view of an example of the display layer taken along line A1-A1′ of FIG. 7;

FIG. 10 is an enlarged cross-sectional view of a display element layer overlapping a first emission area in FIG. 9;

FIG. 11 is a cross-sectional view of an example of the display layer taken along line A3-A3′ of FIG. 7;

FIG. 12 is an enlarged cross-sectional view of the display element layer overlapping the first emission area in FIG. 11;

FIG. 13 is an enlarged cross-sectional view of area ‘T’ in FIG. 12;

FIG. 14 is another embodiment and a cross-sectional view of an example of a display panel taken along line A3-A3′ of FIG. 7;

FIG. 15 is an enlarged cross-sectional view of a display element layer overlapping a first emission area in FIG. 14; and

FIGS. 16 through 25 are cross-sectional views sequentially illustrating a method of fabricating the display element layer of FIG. 11.

FIG. 26 is a block diagram of an electronic device according to one embodiment of the present disclosure.

FIG. 27 is a schematic diagram of an electronic device according to various embodiments of the present disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath”can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” can mean within one or more standard deviations, or within ±30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments will be described in detail with reference to the accompanying drawings.

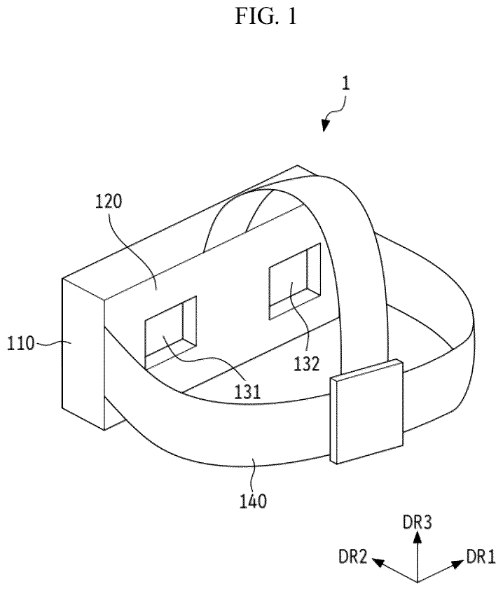

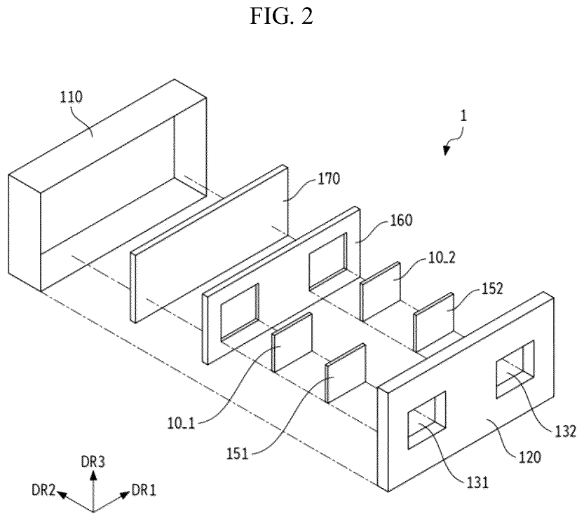

FIG. 1 is a perspective view of a head mounted electronic device 1 according to an embodiment. FIG. 2 is an exploded perspective view of an example of the head mounted electronic device 1 of FIG. 1.

Referring to FIGS. 1 and 2, the head mounted electronic device 1 according to the embodiment includes a display device housing 110, a housing cover 120, a first eyepiece 131, a second eyepiece 132, a head mounted band 140, a first display device 10_1, a second display device 10_2, a middle frame 160, a first optical member 151, a second optical member 152, a control circuit board 170, and a connector.

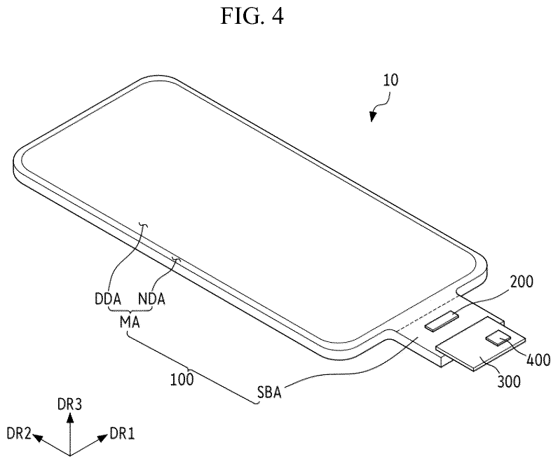

The first display device 10_1 provides an image to a user's left eye, and the second display device 10_2 provides an image to the user's right eye. Each of the first display device 10_1 and the second display device 10_2 is substantially the same as a display device 10 to be described with reference to FIG. 4. Therefore, a description of the first display device 10_1 and the second display device 10_2 will be replaced with descriptions given with reference to FIG. 4.

The first optical member 151 may be disposed between the first display device 10_1 and the first eyepiece 131. The second optical member 152 may be disposed between the second display device 10_2 and the second eyepiece 132. Each of the first optical member 151 and the second optical member 152 may include at least one convex lens.

The middle frame 160 may be disposed between the first display device 10_1 and the control circuit board 170 and may be disposed between the second display device 10_2 and the control circuit board 170. The middle frame 160 supports and fixes the first display device 10_1, the second display device 10_2, and the control circuit board 170.

The control circuit board 170 may be disposed between the middle frame 160 and the display device housing 110. The control circuit board 170 may be connected to the first display device 10_1 and the second display device 10_2 through the connector. The control circuit board 170 may convert an image source received from the outside into digital video data DATA and transmit the digital video data DATA to the first display device 10_1 and the second display device 10_2 through the connector.

The control circuit board 170 may transmit digital video data DATA corresponding to a left image optimized for a user's left eye to the first display device 10_1 and transmit digital video data DATA corresponding to a right image optimized for the user's right eye to the second display device 10_2. Alternatively, the control circuit board 170 may transmit the same digital video data DATA to the first display device 10_1 and the second display device 10_2.

The display device housing 110 houses the first display device 10_1, the second display device 10_2, the middle frame 160, the first optical member 151, the second optical member 152, the control circuit board 170, and the connector. The housing cover 120 is placed to cover an open surface of the display device housing 110. The housing cover 120 may include the first eyepiece 131 on which a user's left eye is placed and the second eyepiece 132 on which the user's right eye is placed. Although the first eyepiece 131 and the second eyepiece 132 are disposed separately in FIGS. 1 and 2, embodiments of the present specification are not limited thereto. The first eyepiece 131 and the second eyepiece 132 may also be combined into one in another embodiment.

The first eyepiece 131 may be aligned with the first display device 10_1 and the first optical member 151, and the second eyepiece 132 may be aligned with the second display device 10_2 and the second optical member 152. Therefore, a user can view an image of the first display device 10_1, which is enlarged as a virtual image by the first optical member 151, through the first eyepiece 131 and can view an image of the second display device 10_2, which is enlarged as a virtual image by the second optical member 152, through the second eyepiece 132.

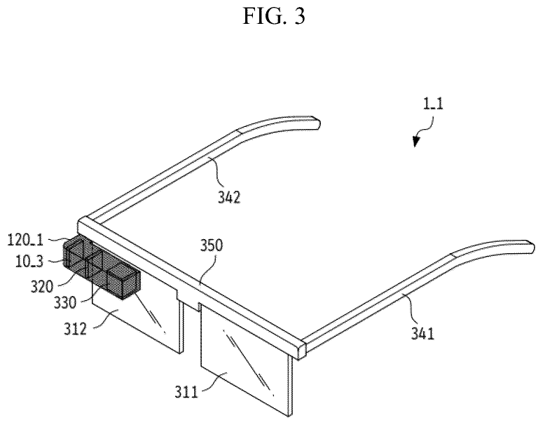

The head mounted band 140 fixes the display device housing 110 to a user's head so that the first eyepiece 131 and the second eyepiece 132 of the housing cover 120 are kept placed on the user's left and right eyes, respectively. When the display device housing 110 is implemented to be lightweight and small, the head mounted electronic device 1 may include an eyeglass frame as illustrated in FIG. 3 instead of the head mounted band 140.

In addition, the head mounted electronic device 1 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 3 is a perspective view of a head mounted electronic device 1_1 according to an embodiment.

Referring to FIG. 3, the head mounted electronic device 1_1 according to the embodiment may be a display device in the form of glasses in which a display device housing 120_1 is implemented to be lightweight and small. The head mounted electronic device 1_1 according to the embodiment may include a display device 10_3, a left lens 311, a right lens 312, a support frame 350, eyeglass frame legs 341 and 342, an optical member 320, an optical path conversion member 330, and the display device housing 120_1.

The display device 10_3 illustrated in FIG. 3 is substantially the same as the display device 10 to be described with reference to FIG. 4.

The display device housing 120_1 may include the display device 10_3, the optical member 320, and the optical path conversion member 330. An image displayed on the display device 10_3 may be enlarged by the optical member 320, may have its optical path converted by the optical path conversion member 330, and then may be provided to a user's right eye through the right lens 312. Accordingly, the user can view, through the right eye, an augmented reality image into which a virtual image displayed on the display device 10_3 and a real image viewed through the right lens 312 are combined.

Although the display device housing 120_1 is disposed at a right end of the support frame 350 in FIG. 3, embodiments of the present specification are not limited thereto. For another example, the display device housing 120_1 may also be disposed at a left end of the support frame 350. In this case, an image of the display device 10_3 may be provided to a user's left eye. Alternatively, the display device housing 120_1 may be disposed at both the left and right ends of the support frame 350. In this case, the user can view an image displayed on the display device 10_3 through both the left and right eyes.

FIG. 4 is a perspective view of a display device 10 according to an embodiment.

Referring to FIG. 4, the display device 10 may be applied to portable electronic devices such as mobile phones, smartphones, tablet personal computers (PCs), mobile communication terminals, electronic notebooks, electronic books, portable multimedia players (PMPs), navigation devices, and ultra-mobile PCs (UMPCs). For example, the display device 10 may be applied as a display unit of a television, a notebook computer, a monitor, a billboard, or an Internet of things (IoT) device. For another example, the display device 10 may be applied to wearable devices such as smart watches, watch phones, glasses-type displays, and head mounted displays.

The display device 10 may have a planar shape similar to a quadrangle. For example, the display device 10 may have a planar shape similar to a quadrangle having short sides in a first direction DR1 and long sides in a second direction DR2. Each corner where a short side extending in the first direction DR1 meets a long side extending in the second direction DR2 may be rounded to have a predetermined curvature or may be right-angled. The planar shape of the display device 10 is not limited to a quadrangular shape but may also be similar to other polygonal shapes, a circular shape, or an oval shape.

The display device 10 may include a display panel 100, a display driver 200, a circuit board 300, and a touch driver 400.

The display panel 100 may include a main area MA and a sub-area SBA. The main area MA may include a display area DDA including pixels that display an image and a non-display area NDA located around the display area DDA.

The display area DDA may emit light from a plurality of emission areas or a plurality of openings which will be described later. For example, the display panel 100 may include a pixel circuit including switching elements, a pixel defining layer defining an emission area or an opening, and a self-light emitting element. For example, the self-light emitting element may include, but is not limited to, at least one of an organic light emitting diode including an organic light emitting layer, a quantum dot light emitting diode including a quantum dot light emitting layer, an inorganic light emitting diode including an inorganic semiconductor, and a micro light emitting diode. The drawings below illustrate a case where the self-light emitting element is an organic light emitting diode.

The non-display area NDA may be an area outside the display area DDA. The non-display area NDA may be defined as an edge area of the main area MA of the display panel 100.

The sub-area SBA may extend from a side of the main area MA. The sub-area SBA may include a flexible material that can be bent, folded, rolled, etc. For example, when the sub-area SBA is bent, it may be overlapped by the main area MA in a thickness direction (e.g., a third direction DR3). The sub-area SBA may include the display driver 200 and a pad unit connected to the circuit board 300. In an embodiment, the sub-area SBA may be omitted, and the display driver 200 and the pad unit may be located in the non-display area NDA.

The display driver 200 may output signals and voltages for driving the display panel 100. The display driver 200 may be formed as an integrated circuit and mounted on the display panel 100 by a chip on glass (COG) method, a chip on plastic (COP) method, or an ultrasonic bonding method. For example, the display driver 200 may be located in the sub-area SBA and may be overlapped by the main area MA in the thickness direction by the bending of the sub-area SBA. For another example, the display driver 200 may be mounted on the circuit board 300.

The circuit board 300 may be attached onto the pad unit of the display panel 100 using an anisotropic conductive film. The circuit board 300 may be a flexible printed circuit board, a printed circuit board, or a flexible film such as a chip on film.

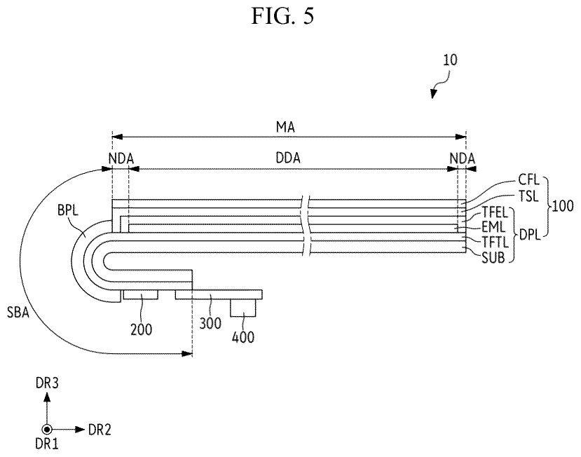

The touch driver 400 may be mounted on the circuit board 300. The touch driver 400 may be connected to a touch sensor layer TSL (see FIG. 5) for sensing and driving a touch on the display device 10.

FIG. 5 is a cross-sectional view of the display device 10 according to the embodiment.

Referring to FIG. 5, the display panel 100 may include a display layer DPL, the touch sensor layer TSL, and a color filter layer CFL. The display layer DPL may include a substrate SUB, a transistor layer TFTL, a display element layer EML, and a thin-film encapsulation layer TFEL.

The substrate SUB may be a base substrate or a base member. The substrate SUB may be a flexible substrate that can be bent, folded, rolled, etc. For example, the substrate SUB may include polymer resin such as polyimide (PI), but embodiments are not limited thereto. In another embodiment, the substrate SUB may include a glass material or a metal material. A major surface of the substrate SUB may be parallel to a plane defined by the first direction DR1 and the second direction DR2.

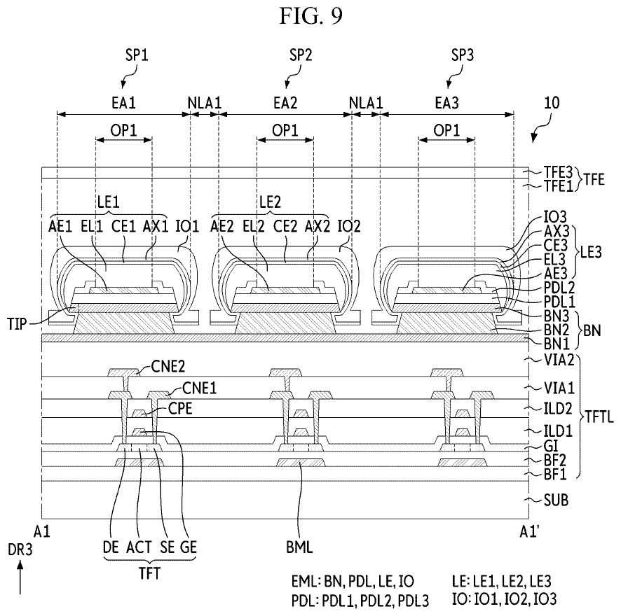

The transistor layer TFTL may be located on the substrate SUB. The transistor layer TFTL may be located in portions overlapping the display area DDA, the non-display area NDA, and the sub-area SBA. The transistor layer TFTL may include a plurality of transistors TFT (see FIG. 9).

The display element layer EML may be located on the transistor layer TFTL. The display element layer EML may be located in a portion overlapping the display device DDA. The display element layer EML may include, but is not limited to, at least one of an organic light emitting diode including an organic light emitting layer, a quantum dot light emitting diode including a quantum dot light emitting layer, an inorganic light emitting diode including an inorganic semiconductor, and a micro light emitting diode.

The thin-film encapsulation layer TFEL may be located on the display element layer EML. The thin-film encapsulation layer TFEL may be located in portions overlapping the display area DDA and the non-display area NDA. The thin-film encapsulation layer TFEL may cover upper and side surfaces of the display element layer EML and may protect the display element layer EML from external oxygen and moisture. The thin-film encapsulation layer TFEL may include at least one inorganic layer and at least one organic layer to encapsulate the display element layer EML. The thin-film encapsulation layer TFEL can be omitted depending on embodiments.

The touch sensor layer TSL may be located on the thin-film encapsulation layer TFEL. The touch sensor layer TSL may be located in the portions overlapping the display area DDA and the non-display area NDA. The touch sensor layer TSL may sense a user's touch in a mutual capacitance manner or a self-capacitance manner. The touch sensor layer TSL can be omitted depending on embodiments.

The color filter layer CFL may be located on the touch sensor layer TSL. The color filter layer CFL may be located in the portions overlapping the display area DDA and the non-display area NDA. The color filter layer CFL may absorb a part of light coming from the outside of the display device 10, thereby reducing reflected light caused by the external light. Therefore, the color filter layer CFL can prevent color distortion caused by reflection of external light.

Since the color filter layer CFL is directly disposed on the touch sensor layer TSL, the display device 10 may not require a separate substrate for the color filter layer CFL. Therefore, a thickness of the display device 10 may be relatively small. The color filter layer CFL can be omitted depending on embodiments.

As illustrated in FIG. 5, a portion of the display panel 100 which overlaps the sub-area SBA may be bent. When the portion of the display panel 100 is bent, the display driver 200, the circuit board 300, and the touch driver 400 may be overlapped by the main area MA in the third direction DR3.

When the portion of the display panel 100 is bent, a bending protection layer BPL may protect a structure located thereunder and overlapping the sub-area SBA from bending stress.

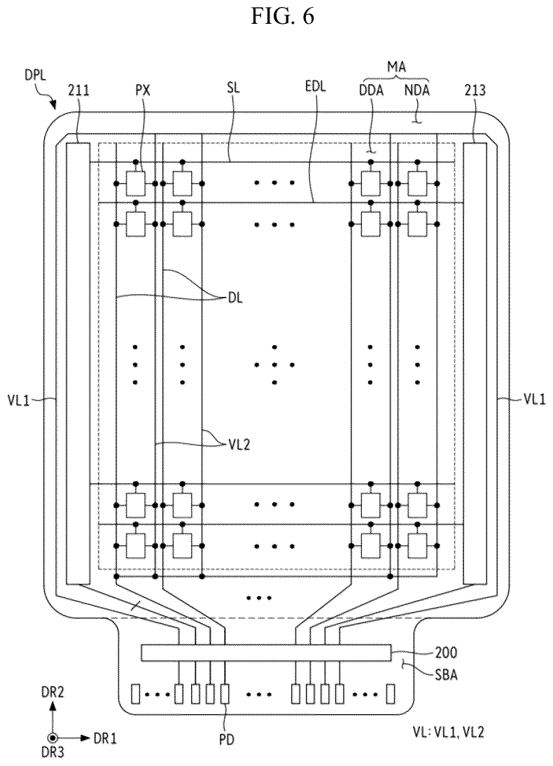

FIG. 6 is a plan view of the display layer DPL of the display device 10 according to the embodiment. As used herein, the “plan view” is a view in a thickness direction (third direction DR3) of the display device 10.

Referring to FIG. 6, the display layer DPL may include a plurality of pixels PX, a plurality of power lines VL connected to the pixels PX, a plurality of scan lines SL, a plurality of emission control lines EDL, and a plurality of data lines DL in a portion overlapping the display area DDA.

The scan lines SL may extend in the first direction DR1 and may be spaced apart from each other in the second direction DR2 intersecting the first direction DR1. The scan lines SL may be arranged along the second direction DR2. The scan lines SL may sequentially supply scan signals to the pixels PX.

The emission control lines EDL may extend in the first direction DR1 and may be spaced apart from each other in the second direction DR2. The emission control lines EDL may be arranged along the second direction DR2. The emission control lines EDL may sequentially supply emission signals to the pixels PX.

The data lines DL may extend in the second direction DR2 and may be spaced apart from each other in the first direction DR1. The data lines DL may be arranged along the first direction DR1. The data lines DL may supply data voltages to the pixels PX. The data voltages may determine respective luminances of the pixels PX.

The power lines VL may include a main power line VL1 and sub-power lines VL2. At least any one of a first power voltage (high potential voltage) or a second power voltage (low potential voltage) may be transmitted to the sub-power lines VL2 through the main power line VL1 overlapping the non-display area NDA. The main power line VL1 and the sub-power lines VL2 may be collectively referred to as the power lines VL.

The non-display area NDA may surround the display area DDA. The non-display area NDA may include a scan driver 211 and an emission control driver 213.

The scan driver 211 may be disposed outside one side of the display area DDA or on one side of the non-display area NDA. The scan driver 211 may include a plurality of driving transistors which generate gate signals based on a gate control signal.

The emission control driver 213 may be disposed outside the other side of the display area DDA or on the other side of the non-display area NDA. The emission control driver 213 may include a plurality of emission control transistors which generate emission signals based on an emission control signal.

The display layer DPL included in an embodiment may include the display driver 200 and a plurality of pad electrodes PD in a portion overlapping the sub-area SBA. The pad electrodes PD may be spaced apart from each other in the first direction DR1 and may be connected to different lines, respectively.

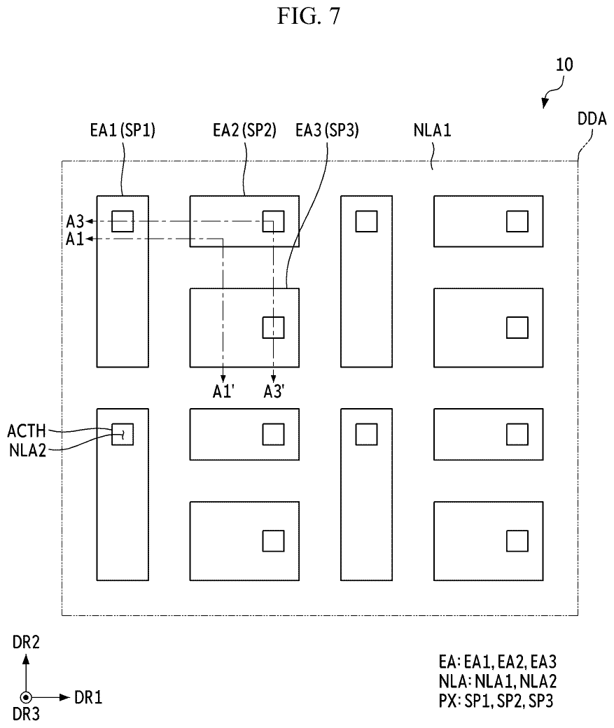

FIG. 7 is a layout view illustrating the arrangement of a plurality of pixels PX in the display area DDA of FIG. 6.

Referring to FIG. 7, each of the pixels PX of an embodiment may include a first subpixel SP1, a second subpixel SP2, and a third subpixel SP3 located in a portion overlapping the display area DDA. The first subpixel SP1, the second subpixel SP2, and the third subpixel SP3 may be spaced apart from each other.

The display panel 100 of an embodiment may include emission areas EA located in portions overlapping the pixels PX and a non-emission area NLA. The emission areas EA may be portions from which light is emitted by the pixels PX, and the non-emission area NLA may be a portion from which light is not emitted.

The emission areas EA may include a first emission area EA1 which is an emission area of the first subpixel SP1, a second emission area EA2 which is an emission area of the second subpixel SP2, and a third emission area EA3 which is an emission area of the third subpixel SP3.

In some embodiments, the emission areas EA may have a quadrangular planar shape (e.g., a stripe structure). When the emission areas EA have a stripe structure, the first emission area EA1 and the second emission area EA2 as well as the first emission area EA1 and the third emission area EA3 may neighbor each other in the first direction DR1, and the second emission area EA2 and the third emission area EA3 may neighbor each other in the second direction DR2. The area of the first emission area EA1, the area of the second emission area EA2, and the area of the third emission area EA3 may be different from each other. However, embodiments are not limited thereto, and the emission areas EA may also have a planar shape other than a quadrangular shape, such as a hexagonal, other polygonal, circular, oval, or irregular shape in another embodiment.

The first emission area EA1, the second emission area EA2, and the third emission area EA3 of an embodiment may emit light of different colors. For example, the first emission area EA1 may emit red light, the second emission area EA2 may emit green light, and the third emission area EA3 may emit blue light. However, embodiments are not limited thereto. Depending on embodiments, the first emission area EA1, the second emission area EA2, and the third emission area EA3 can also emit light of the same color.

The non-emission area NLA may include a first non-emission area NLA1 and second non-emission areas NLA2. The first non-emission area NLA1 may surround each of the first emission area EA1, the second emission area EA2 and the third emission area EA3 and may prevent color mixing of light emitted from each of the first emission area EA1, the second emission area EA2 and the third emission area EA3.

The second non-emission areas NLA2 may be surrounded by the emission areas EA. The second non-emission areas NLA2 may be located in portions overlapping anode contact holes ACTH of the display panel 100. The placement of each anode contact hole ACTH can vary within an emission area EA.

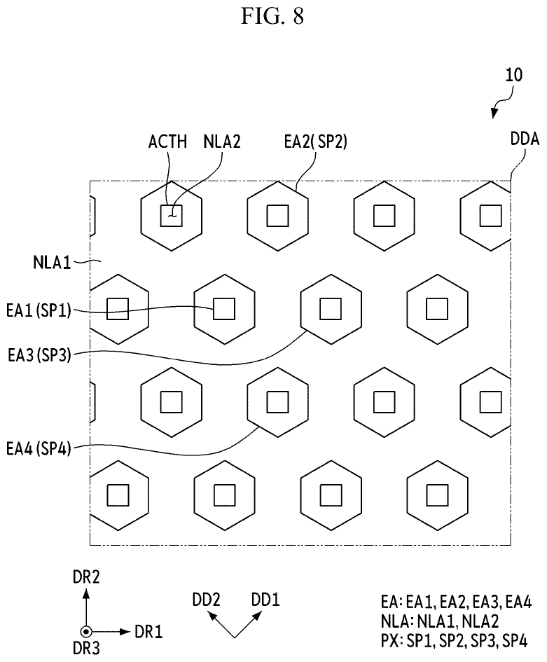

FIG. 8 is another example and a layout view illustrating the arrangement of a plurality of pixels PX in the display area DDA of FIG. 6.

Referring to FIG. 8, emission areas EA may be disposed in a PenTile® structure having a rhombic arrangement or in a hexagonal structure having a hexagonal arrangement.

In some embodiments, when the emission areas EA have a pentile or hexagonal structure, each of the pixels PX may have a first subpixel SP1, a second subpixel SP2, a third subpixel SP3 and a fourth subpixel SP4, and the emission areas EA may include a first emission area EA1 which is an emission area of the first subpixel SP1, a second emission area EA2 which is an emission area of the second subpixel SP2, a third emission area EA3 which is an emission area of the third subpixel SP3 and a fourth emission area EA4 which is an emission area of the fourth subpixel SP4.

In some embodiments, when the emission areas EA have a pentile or hexagonal structure, the first emission area EA1 and the third emission area EA3 may neighbor each other in the first direction DR1, and the second emission area EA2 and the fourth emission area EA4 may neighbor each other in the second direction DR2. In addition, the first emission area EA1 and the second emission area EA2 may neighbor each other in a first diagonal direction DD1, and the second emission area EA2 and the third emission area EA3 may neighbor each other in a second diagonal direction DD2. In addition, the first emission area EA1 and the fourth emission area EA4 may neighbor each other in the second diagonal direction DD2, and the third emission area EA3 and the fourth emission area EA4 may neighbor each other in the first diagonal direction DD1. The first diagonal direction DD1 may be a direction between the first direction DR1 and the second direction DR2 and a direction inclined at 45 degrees with respect to the first direction DR1 and the second direction DR2, and the second diagonal direction DD2 may be a direction orthogonal to the first diagonal direction DD1.

A non-emission area NLA may include a first non-emission NLA1 and second non-emissions NLA2. The second non-emission areas NLA2 may be located in portions overlapping anode contact holes ACTH. Redundant descriptions will be omitted.

FIG. 9 is a cross-sectional view of an example of the display layer DPL taken along line A1-A1′ of FIG. 7. FIG. 9 illustrates a cross-sectional structure of the first subpixel SP1, the second subpixel SP2, and the third subpixel SP3 not overlapping the anode contact holes ACTH in a portion overlapping the display area DDA of the display panel 100.

Referring to FIG. 9, the transistor layer TFTL may be located on the substrate SUB. The transistor layer TFTL may include a first buffer layer BF1, bottom metal layers BML, a second buffer layer BF2, transistors TFT, a gate insulating layer GI, a first insulating layer ILD1, capacitor electrodes CPE, a second insulating layer ILD2, first connection electrodes CNE1, a first via-layer VIA1, second connection electrodes CNE2, and a second via-layer VIA2.

The first buffer layer BF1 may be located on the substrate SUB. The first buffer layer BF1 may include an inorganic layer that can prevent penetration of air or moisture. For example, the first buffer layer BF1 may include a plurality of inorganic layers stacked alternately.

The bottom metal layers BML may be located on the first buffer layer BF1. Each of the bottom metal layer BML may include a conductive metal and may be, for example, a single layer or a multilayer made of any one or more of molybdenum (Mo), aluminum (Al), chromium (Cr), gold (Au), titanium (Ti), nickel (Ni), neodymium (Nd), copper (Cu), and alloys thereof.

The second buffer layer BF2 may cover the first buffer layer BF1 and the bottom metal layers BML. The second buffer layer BF2 may include an inorganic layer that can prevent penetration of air or moisture. For example, the second buffer layer BF2 may include a plurality of inorganic layers stacked alternately.

The transistors TFT may be disposed on the second buffer layer BF2 and may form pixel circuits connected to a plurality of pixels, respectively. For example, each of the transistors TFT may be a driving transistor or a switching transistor of a pixel circuit.

Each of the transistors TFT may include an active layer ACT, a source electrode SE, a drain electrode DE, and a gate electrode GE. The active layer ACT may be located on the second buffer layer BF2. The active layer ACT may be overlapped by the gate electrode GE in the third direction DR3 and may be insulated from the gate electrode GE by the gate insulating layer GI. In portions of the active layer ACT, the material of the active layer ACT may be made conductive to form the source electrode SE and the drain electrode DE.

The gate insulating layer GI may be located on the active layers ACT. The gate insulating layer GI may cover the active layers ACT and the second buffer layer BF2 and may insulate the active layers ACT from the gate electrodes GE. The gate insulating layer GI may include contact holes through which the first connection electrodes CNE1 pass.

The gate electrodes GE may be located on the gate insulating layer GI. The gate electrodes GE may overlap the active layers ACT with the gate insulating layer GI interposed between them in a plan view. The gate electrodes GE may include a conductive metal and may each be, for example, a single layer or a multilayer made of any one or more of molybdenum (Mo), aluminum (Al), chromium (Cr), gold (Au), titanium (Ti), nickel (Ni), neodymium (Nd), copper (Cu), and alloys thereof.

The first insulating layer ILD1 may cover the gate electrodes GE and the gate insulating layer GI. The first insulating layer ILD1 may include contact holes through which the first connection electrodes CNE1 pass. The contact holes of the first insulating layer ILD1 may be connected to the contact holes of the gate insulating layer GI and contact holes of the second insulating layer ILD2.

The capacitor electrodes CPE may be located on the first insulating layer ILD1. The capacitor electrodes CPE may overlap the gate electrodes GE in the third direction DR3. The capacitor electrodes CPE and the gate electrodes GE may form capacitances.

The second insulating layer ILD2 may cover the capacitor electrodes CPE and the first insulating layer ILD1. The second insulating layer ILD2 may include the contact holes through which the first connection electrodes CNE1 pass. The contact holes of the second insulating layer ILD2 may be connected to the contact holes of the first insulating layer ILD1 and the contact holes of the gate insulating layer GI.

The first connection electrodes CNE1 may be located on the second insulating layer ILD2. The first connection electrodes CNE1 may electrically connect the drain electrodes DE of the transistors TFT to the second connection electrodes CNE2. The first connection electrodes CNE1 may be inserted into the contact holes formed in the first insulating layer ILD1, the second insulating layer ILD2, and the gate insulating layer GI to contact the drain electrodes DE of the transistors TFT.

The first via-layer VIA1 may cover the first connection electrodes CNE1 and the second insulating layer ILD2. The first via-layer VIA1 may planarize structures thereunder. The first via-layer VIA1 may include contact holes through which the second connection electrodes CNE2 pass.

The first via-layer VIA1 may include an organic insulating material. For example, the first via-layer VIA1 may include acrylic resin, polyimide, polyamide, benzocyclobutene, phenolic resin, or the like.

The second connection electrodes CNE2 may be located on the first via-layer VIA1. The second connection electrodes CNE2 may be inserted into the contact holes formed in the first via-layer VIA1 to contact the first connection electrodes CNE1. The second connection electrodes CNE2 may electrically connect the first connection electrodes CNE1 to anodes AE. The second via-layer VIA2 may cover the second connection electrodes CNE2 and the first via-layer VIA1.

The second via-layer VIA2 may include an organic material. For example, the second via-layer VIA2 may include acrylic resin, polyimide, polyamide, benzocyclobutene, phenolic resin, or the like.

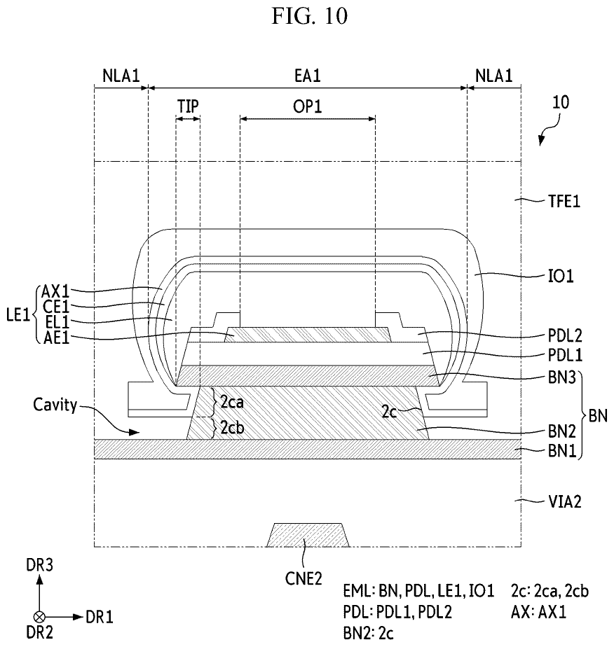

FIG. 10 is an enlarged cross-sectional view of the display element layer EML overlapping the first emission area EA1 in FIG. 9.

Referring to FIGS. 9 and 10, the display element layer EML of an embodiment may be disposed on the transistor layer TFTL. The display element layer EML may include a bank structure BN, a pixel defining layer PDL, light emitting elements LE, and element inorganic layers IO.

The bank structure BN of an embodiment may be disposed on the second via-layer VIA2 in portions overlapping the emission areas EA. The bank structure BN may include a first bank layer BN1, a second bank layer BN2, and a third bank layer BN3.

The first bank layer BN1, the second bank layer BN2, and the third bank layer BN3 may be sequentially stacked in the third direction DR3.

The first bank layer BN1 of an embodiment may be located on the second via-layer VIA2. The first bank layer BN1 may cover the entire surface of the second via-layer VIA2.

The first bank layer BN1 may include a conductive metal having etch resistance. For example, the first bank layer BN1 may be titanium (Ti). The first bank layer BN1 may assist in applying a low potential voltage to cathodes CE.

The second bank layer BN2 of an embodiment may be located on the first bank layer BN1 to contact the first bank layer BN1. The second bank layer BN2 may be electrically connected to the first bank layer BN1. The second bank layer BN2 may assist in electrically connecting the first bank layer BN1 to the cathodes CE. The second bank layer BN2 may be formed in a plurality of pieces of the second bank layer BN2 may be located in portions overlapping the first emission area EA1, the second emission area EA2 and the third emission area EA3, respectively, and may be spaced apart from each other.

The second bank layer BN2 may include a metal having high electrical conductivity. For example, the second bank layer BN2 may include aluminum (Al).

In some embodiments, the second bank layer BN2 may include first side surfaces 2c. The first side surfaces 2c of the second bank layer BN2 may be surfaces that face the first non-emission area NLA1.

In some embodiments, each of the first side surfaces 2c of the second bank layer BN2 may be divided into a first portion 2ca and a second portion 2cb depending on a portion that it contacts. The first portion 2ca may be a portion that contacts a first auxiliary electrode AX1, and the second portion 2cb may be a portion that does not contact the first auxiliary electrode AX1. According to an embodiment, the second portion 2cb may contact an organic encapsulation layer TFE1, but embodiments are not limited thereto. The third bank layer BN3 may be formed in a plurality of pieces of the third bank layer BN3 may be located in the portions overlapping the first emission area EA1, the second emission area EA2 and the third emission area EA3, respectively, and may be spaced apart from each other.

The third bank layer BN3 of an embodiment may be located on the second bank layer BN2. The third bank layer BN3 may include a conductive metal having etch resistance. For example, the third bank layer BN3 may be titanium (Ti).

The third bank layer BN3 may have tips TIP that protrude more than the first side surfaces 2c of the second bank layer BN2 toward the first non-emission area NLA1. In a process of fabricating the display device 10, the third bank layer BN3 may have a lower etch rate than the second bank layer BN2. Therefore, the third bank layer BN3 may have the tips TIP that protrude more than the second bank layer BN2 in the first direction DR1. Accordingly, the first side surfaces 2c of the second bank layer BN2 and the tips TIP of the third bank layer BN3 may form an undercut. In other words, the bank structure BN of the embodiment may have an overhang structure.

Since the bank structure BN of the embodiment includes the tips TIP that protrude toward the first non-emission area NLA1, light emitting layers EL and the cathodes CE can be formed on the bank structure BN without using a fine metal mask in the process of fabricating the display device 10. In other words, the light emitting layers EL and the cathodes CE overlapping the first emission area EA1, the second emission area EA2 and the third emission area EA3 may be separated by the tips TIP of the bank structure BN. The fabrication process will be described later.

In some embodiments, a height of the second bank layer BN2 may be higher than a height of the first bank layer BN1 and a height of the third bank layer BN3.

The pixel defining layer PDL of an embodiment may be located on the bank structure BN in the portions overlapping the emission areas EA.

The pixel defining layer PDL may include a first pixel defining layer PDL1 and a second pixel defining layer PDL2 stacked sequentially. The first pixel defining layer PDL1 and the second pixel defining layer PDL2 may be sequentially stacked in the third direction DR3.

The first pixel defining layer PDL1 of an embodiment may be located on the third bank layer BN3. The first pixel defining layer PDL1 may overlap the tips TIP of the third bank layer BN3 in the third direction DR3.

The first pixel defining layer PDL1 may insulate the bank structure BN from the anodes AE. Accordingly, the first pixel defining layer PDL1 can solve a short-circuit between the bank structure BN and the anodes AE and solve a driving failure of the light emitting element.

The first pixel defining layer PDL1 may include an inorganic insulating material. For example, the first pixel defining layer PDL1 may include at least one of silicon nitride, silicon oxide, and silicon oxynitride.

The second pixel defining layer PDL2 of an embodiment may be located on the first pixel defining layer PDL1. The second pixel defining layer PDL2 may define first openings OP1 and may expose the anodes AE in portions overlapping the first openings OP1 in a plan view. In other words, the second pixel defining layer PDL2 may surround the first openings OP1 and cover edges of the anodes AE. The second pixel defining layer PDL2 may overlap the tips TIP of the third bank layer BN3 in the third direction DR3.

The second pixel defining layer PDL2 may include an inorganic insulating material. For example, the second pixel defining layer PDL2 may include at least one of silicon nitride, silicon oxide, and silicon oxynitride.

The light emitting elements LE of an embodiment may be located on the pixel defining layer PDL. The light emitting elements LE may overlap the bank structure BN in the third direction DR3. In the display device 10 of the embodiment, since the light emitting elements LE are formed on the bank structure BN, a high-resolution display device with a relatively narrow gap between the light emitting elements LE can be implemented.

The light emitting elements LE may include a first light emitting element LE1 disposed in the first emission area EA1, a second light emitting element LE2 disposed in the second emission area EA2, and a third light emitting element LE3 disposed in the third emission area EA3. The first light emitting element LE1, the second light emitting element LE2, and the third light emitting element LE3 may be spaced apart from each other.

The first light emitting element LE1 may include a first anode AE1, a first light emitting layer EL1, a first cathode CE1, and the first auxiliary electrode AX1. The second light emitting element LE2 may include a second anode AE2, a second light emitting layer EL2, a second cathode CE2, and a second auxiliary electrode AX2. The third light emitting element LE3 may include a third anode AE3, a third light emitting layer EL3, a third cathode CE3, and a third auxiliary electrode AX3.

The first light emitting element LE1, the second light emitting element LE2, and the third light emitting element LE3 may emit light of different colors. For example, the first light emitting element LE1 may emit red light, the second light emitting element LE2 may emit green light, and the third light emitting element LE3 may emit blue light.

The anodes AE of an embodiment may be located on the first pixel defining layer PDL1. The anodes AE may include the first anode AE1, the second anode AE2, and the third anode AE3. The first anode AE1 may be located in a portion overlapping the first emission area EA1, the second anode AE2 may be located in a portion overlapping the second emission area EA2, and the third anode AE3 may be located in a portion overlapping the third emission area EA3.

The anodes AE may have a stacked structure of a material layer having a high work function such as indium-tin-oxide (ITO), indium-zinc-oxide (IZO), zinc oxide (ZnO) or indium oxide (In₂O₃) and a reflective material layer such as silver (Ag), magnesium (Mg), aluminum (Al), platinum (Pt), lead (Pb), palladium (Pd), gold (Au), nickel (Ni), neodymium (Nd), iridium (Ir), chromium (Cr), lithium (Li), or a mixture thereof. For example, the anodes AE may have, but are not limited to, a multilayer structure of ITO/Mg, ITO/MgF, ITO/Ag, or ITO/Ag/ITO.

The light emitting layers EL of an embodiment may be located on the anodes AE. The light emitting layers EL may be organic light emitting layers made of an organic material and may be formed on the anodes AE through a deposition process. The light emitting layers EL may contact the anodes AE in the portions overlapping the first openings OP1 in a plan view and may cover the entirety of the second pixel defining layer PDL2.

The light emitting layers EL may include the first light emitting layer EL1, the second light emitting layer EL2, and the third light emitting layer EL3. The first light emitting layer EL1 may be located in the portion overlapping the first emission area EA1, the second light emitting layer EL2 may be located in the portion overlapping the second emission area EA2, and the third light emitting layer EL3 may be located in the portion overlapping the third emission area EA3.

The first light emitting layer EL1, the second light emitting layer EL2, and the third light emitting layer EL3 may emit light of different colors. For example, the first light emitting layer EL1 may emit red light, the second light emitting layer EL2 may emit green light, and the third light emitting layer EL3 may emit blue light. However, embodiments are not limited thereto.

The cathodes CE of an embodiment may be located on the light emitting layers EL. The cathodes CE may cover the entirety of the light emitting layers EL.

The cathodes CE may include a transparent conductive material to transmit light generated from the light emitting layers EL. For example, the cathodes CE may include a material layer having a small work function such as Li, Ca, LiF/Ca, LiF/Al, Al, Mg, Ag, Pt, Pd, Ni, Au Nd, Ir, Cr, BaF, Ba, or a compound or mixture thereof (e.g., a mixture of Ag and Mg). The cathodes CE may further include a transparent metal oxide layer disposed on the material layer having a small work function.

The cathodes CE may include the first cathode CE1, the second cathode CE2, and the third cathode CE3. The first cathode CE1 may be located in the portion overlapping the first emission area EA1, the second cathode CE2 may be located in the portion overlapping the second emission area EA2, and the third cathode CE3 may be located in the portion overlapping the third emission area EA3.

The first cathode CE1, the second cathode CE2, and the third cathode CE3 may be spaced apart from each other. The first cathode CE1, the second cathode CE2, and the third cathode CE3 may not be directly connected but may be electrically connected through auxiliary electrodes AX and the bank structure BN.

The auxiliary electrodes AX of an embodiment may be located on the cathodes CE. The auxiliary electrodes AX may cover the entirety of the cathodes CE.

The auxiliary electrodes AX may include a transparent conductive material (TCO). For example, the auxiliary electrodes AX may include indium-zinc-oxide (IZO).

The auxiliary electrodes AX may include the first auxiliary electrode AX1, the second auxiliary electrode AX2, and the third auxiliary electrode AX3. The first auxiliary electrode AX1 may be located in the portion overlapping the first emission area EA1, the second auxiliary electrode AX2 may be located in the portion overlapping the second emission area EA2, and the third auxiliary electrode AX3 may be located in the portion overlapping the third emission area EA3.

The first auxiliary electrode AX1, the second auxiliary electrode AX2, and the third auxiliary electrode AX3 may be spaced apart from each other. The first auxiliary electrode AX1, the second auxiliary electrode AX2, and the third auxiliary electrode AX3 may not be directly connected but may be electrically connected through the bank structure BN. Specifically, each auxiliary electrode AX (e.g., the first auxiliary electrode AX1) may cover the entirety of the tips TIP of the third bank layer BN3 and may contact the first side surfaces 2c of the second bank layer BN2. Accordingly, the first auxiliary electrode AX1, the second auxiliary electrode AX2, and the third auxiliary electrode AX3 may be electrically connected to each other through the second bank layer BN2 and the first bank layer BN1.

Each auxiliary electrode AX (e.g., the first auxiliary electrode AX1) may be spaced apart from the first bank layer BN1 in the third direction DR3. In other words, each auxiliary electrode AX may be spaced apart from the first bank layer BN1 in the third direction DR3 with cavities Cavity between them. The cavities Cavity formed between the auxiliary electrode AX and the first bank layer BN1 may be portions where a material that forms the light emitting layers EL and a material that forms the cathodes CE were temporarily located and then removed during the fabrication process.

Since the display device 10 of the embodiment includes the cavities Cavity described above, it can be seen that the light emitting layer EL and the cathode CE are formed by deposition and etching processes without using a mask in the process of fabricating the display device 10.

The element inorganic layers IO of an embodiment may be located on the light emitting elements LE. The element inorganic layers IO may completely cover the light emitting elements LE and prevent oxygen or moisture from penetrating into the light emitting elements LE. The element inorganic layers IO may not contact the bank structure BN.

The element inorganic layers IO may include an inorganic insulating material. For example, the element inorganic layers IO may include any one of silicon nitride, silicon oxide, and silicon oxynitride.

The element inorganic layers IO may include a first element inorganic layer IO1, a second element inorganic layer IO2, and a third element inorganic layer IO3. The first element inorganic layer IO1 may be disposed on the first light emitting element LE1 in the first emission area EA1, the second element inorganic layer IO2 may be disposed on the second light emitting element LE2 in the second emission area EA2, and the third element inorganic layer IO3 may be located on the third light emitting element LE3 in the third emission area EA3. The first element inorganic layer IO1, the second element inorganic layer IO2, and the third element inorganic layer IO3 may be spaced apart from each other in a portion overlapping the non-emission area NLA.

In the drawings, the first element inorganic layer IO1, the second element inorganic layer IO2, and the third element inorganic layer IO3 appear to be formed on the same layer. However, in the process of fabricating the display device 10, the first element inorganic layer IO1 may be formed after the first light emitting element LE1 is formed, the second element inorganic layer IO2 may be formed after the second light emitting element LE2 is formed, and the third element inorganic layer IO3 may be formed after the third light emitting element LE3 is formed.

Each element inorganic layer IO (e.g., the first element inorganic layer IO1) may be spaced apart from the first bank layer BN1 in the third direction DR3 with the cavities Cavity between them. Redundant descriptions will be omitted.

The thin-film encapsulation layer TFEL of an embodiment may be located on the display element layer EML. The thin-film encapsulation layer TFEL may include the organic encapsulation layer TFE1 and an inorganic encapsulation layer TFE3.

The organic encapsulation layer TFE1 of an embodiment may be located on the element inorganic layers IO. For example, the organic encapsulation layer TFE1 may contact and cover the entirety of the first element inorganic layer IO1, the second element inorganic layer IO2, and the third element inorganic layer IO3.

The organic encapsulation layer TFE1 may flatten steps formed according to profiles of structures thereunder. In addition, the organic encapsulation layer TFE1 may fill the cavities Cavity formed between the first bank layer BN1 and the element inorganic layers IO in the portions overlapping the emission areas EA. The organic encapsulation layer TFE1 can be omitted depending on embodiments.

The organic encapsulation layer TFE1 may include a polymer-based material. For example, the organic encapsulation layer TFE1 may include acrylic resin, silicone resin, epoxy resin, silicone acrylic resin, polyimide, polyethylene, etc.

The inorganic encapsulation layer TFE3 of an embodiment may be located on the organic encapsulation layer TFE1. The inorganic encapsulation layer TFE3 may protect structures thereunder from moisture and oxygen. The inorganic encapsulation layer TFE3 can be omitted depending on embodiments.

The inorganic encapsulation layer TFE3 may include an inorganic insulating material. For example, the inorganic encapsulation layer TFE3 may include any one of silicon nitride, silicon oxide, and silicon oxynitride.

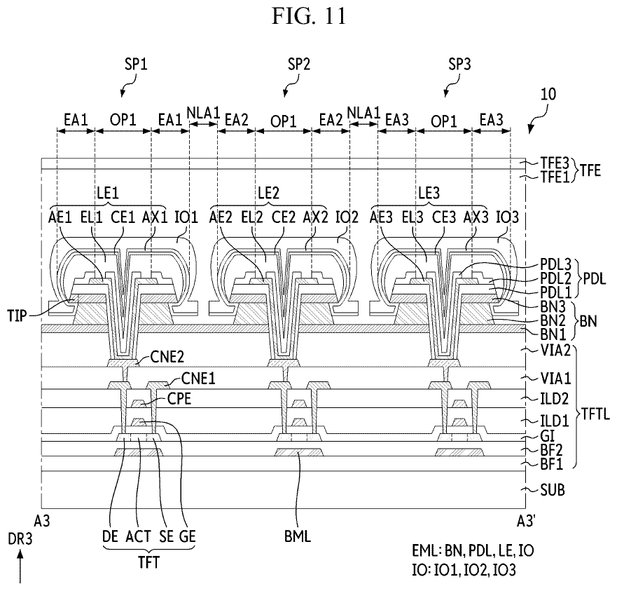

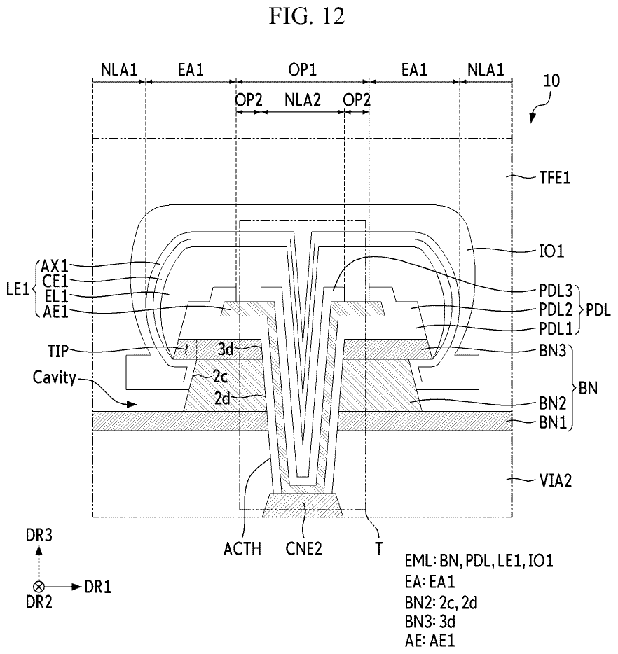

FIG. 11 is a cross-sectional view of an example of the display layer DPL taken along line A3-A3′ of FIG. 7. FIG. 12 is an enlarged cross-sectional view of the display element layer DPL overlapping the first emission area EA1 in FIG. 11. FIG. 11 illustrates a cross-sectional structure of the first subpixel SP1, the second subpixel SP2, and the third subpixel SP3 overlapping the anode contact holes ACTH of the display device 10. Common descriptions will be omitted below, and the structure of the display element layer EML overlapping the anode contact holes ACTH will be described below.

Referring to FIGS. 11 and 12, the anode contact holes ACTH of an embodiment may be defined to overlap the second non-emission area NLA2. Specifically, the anode contact holes ACTH may be located in the portions overlapping the first openings OP1 defined by the second pixel defining layer PDL2. The anode contact holes ACTH may penetrate the second via-layer VIA2. Accordingly, the second connection electrodes CNE2 overlapping the anode contact holes ACTH may be exposed. The anode contact holes ACTH may assist in electrically connecting the anodes AE of the display element layer EML to the transistors TFT of the transistor layer TFTL.

Portions of the bank structure BN included in the display element layer EML may be penetrated by the anode contact holes ACTH. Specifically, portions of the first bank layer BN1 which overlap the first openings OP1 in a plan view may be penetrated by the anode contact holes ACTH, and the first bank layer BN1 may surround the anode contact holes ACTH. In addition, portions of the second bank layer BN2 which overlap the first openings OP1 may be penetrated by the anode contact holes ACTH, and the second bank layer BN2 may surround the anode contact holes ACTH. In addition, portions of the third bank layer BN3 which overlap the first openings OP1 in a plan view may be penetrated by the anode contact holes ACTH, and the third bank layer BN3 may surround the anode contact holes ACTH.

For example, if the anode contact holes ACTH are spaced apart and formed separately from the bank structure BN in an area not overlapping the bank structure BN, the display device 10 may require a separate anode contact hole area, which may make it difficult to implement high resolution.

In the display device 10 of the embodiment, since the anode contact holes ACTH are formed to penetrate the bank structure BN, the anodes AE and the transistors TFT can be electrically connected without a separate anode contact hole area. Therefore, the display device 10 of the embodiment can be applied to high-resolution electronic devices.

In some embodiments, the shape of the bank structure BN facing the first non-emission area NLA1 and the shape of the bank structure BN facing the anode contact holes ACTH may be different from each other. For example, the bank structure BN facing the first non-emission area NLA1 may have a shape in which the tips TIP of the third bank layer BN3 protrude more than the first side surfaces 2c of the second bank layer BN2. In contrast, side surfaces 3d of the third bank layer BN3 facing the anode contact hole ACTH may be in line with second side surfaces 2d of the second bank layer BN2. This may be caused by simultaneous etching of the second bank layer BN2 and the third bank layer BN3 to form the anode contact holes ACTH in the process of fabricating the display device 10. The fabrication process will be described later.

The first pixel defining layer PDL1 included in the display element layer EML may cover the anode contact holes ACTH along the shape of the anode contact holes ACTH in portions overlapping the anode contact holes ACTH. The first pixel defining layer PDL1 may expose the second connection electrodes CNE2 in the portions overlapping the anode contact holes ACTH.

In some embodiments, the first pixel defining layer PDL1 may contact and cover the second side surfaces 2d of the second bank layer BN2 and the side surfaces 3d of the third bank layer BN3.

As described above, the first pixel defining layer PDL1 may insulate the bank structure BN from the anodes AE. Therefore, the bank structure BN may be spaced apart from the anodes AE with the first pixel defining layer PDL1 interposed between them in portions overlapping the anodes AE in the third direction DR3.

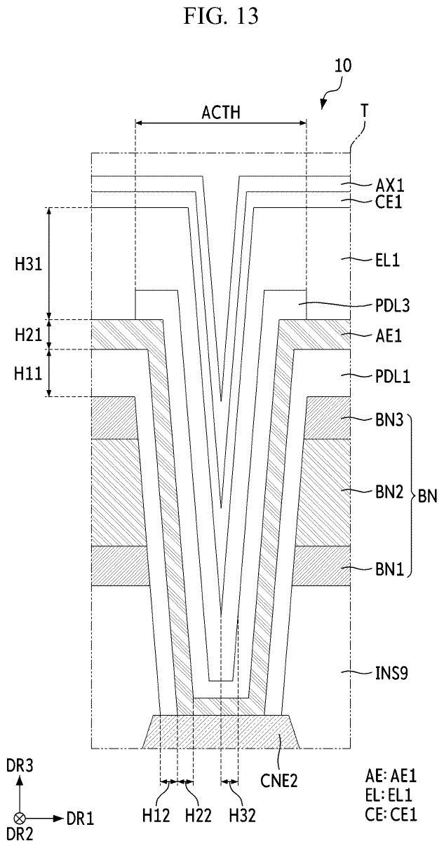

FIG. 13 is an enlarged cross-sectional view of area ‘T’ in FIG. 12.

Referring to FIGS. 11 through 13, a first thickness H11 of the first pixel defining layer PDL1 not overlapping the anode contact holes ACTH of the embodiment may be greater than a second thickness H12 of the first pixel defining layer PDL1 overlapping the anode contact holes ACTH in the third direction DR3. This may be caused by a reduction in step coverage characteristics of a deposition material according to the degree to which each anode contact hole ACTH is recessed in the third direction DR3 or the taper angle formed by each anode contact hole ACTH. For example, the second thickness H12 may be 30% or less of the first thickness H11. The above-described thicknesses may have the same meaning as heights and/or widths.

The anodes AE included in the display element layer EML may cover the anode contact holes ACTH along the shape of the anode contact holes ACTH in the portions overlapping the anode contact holes ACTH. The anodes AE may contact the second connection electrodes CNE2 in the portions overlapping the anode contact holes ACTH. Accordingly, the anodes AE may be electrically connected to the second connection electrodes CNE2. As described above, the anodes AE may be electrically connected to the transistors TFT through the second connection electrodes CNE2.

In some embodiments, the anodes AE may cover the second side surfaces 2d of the second bank layer BN2 and the side surfaces 3d of the third bank layer BN3 in the portions overlapping the anode contact holes ACTH.

In an embodiment, a first thickness H21 of each anode AE (e.g., the first anode AE1) not overlapping an anode contact hole ACTH may be greater than a second thickness H22 of the anode AE (e.g., the first anode AE1) overlapping the anode contact hole ACTH in the third direction DR3. For example, the second thickness H22 may be 30% or less of the first thickness H21. Other redundant descriptions will be omitted.

A third pixel defining layer PDL3 included in the display element layer EML may be located in the portions overlapping the emission areas EA. Each second opening OP2 may be defined between the third pixel defining layer PDL3 and the second pixel defining layer PDL2 neighboring the third pixel defining layer PDL3. Accordingly, an anode AE may be exposed in a portion overlapping each second opening OP2 and may contact a light emitting layer EL in the portion overlapping each second opening OP2 in the third direction DR3.

The third pixel defining layer PDL3 may cover the anode contact holes ACTH along the shape of the anode contact holes ACTH in the portions overlapping the anode contact holes ACTH. The third pixel defining layer PDL3 may contact and cover the entirety of the anodes AE in the portions overlapping the anode contact holes ACTH. The third pixel defining layer PDL3 may insulate the anodes AE from the cathodes CE in the portions overlapping the anode contact holes ACTH.

For example, if small particles are formed on the anodes AE in the portions overlapping the anode contact holes ACTH, a short-circuit may occur between the anodes AE and the cathodes CE due to the light emitting layers EL and the cathodes CE formed to cover the small particles along the shape of the small particles. Accordingly, this may cause a driving failure of the light emitting element.

In the display device 10 of the embodiment, since the third pixel defining layer PDL3 is disposed between the anodes AE and the cathodes CE in the portions overlapping the anode contact holes ACTH, it is possible to solve the short-circuit between the anodes AE and the cathodes CE and a driving failure of the light emitting element.

In some embodiments, the third pixel defining layer PDL3 may include the same material as the second pixel defining layer PDL2.

The light emitting layers EL included in the display element layer EML may be located on the second pixel defining layer PDL2 and the third pixel defining layer PDL3 and may cover the entirety of the second pixel defining layer PDL2 and the third pixel defining layer PDL3.

The light emitting layers EL may cover the anode contact holes ACTH along the shape of the anode contact holes ACTH in the portions overlapping the anode contact holes ACTH. The light emitting layers EL may cover the entirety of the anodes AE in the portions overlapping the anode contact holes ACTH. However, the light emitting layers EL may be spaced apart from the anodes AE with the third pixel defining layer PDL3 interposed between them in the portions overlapping the anode contact holes ACTH and may contact the anodes AE in portions not overlapping the anode contact holes ACTH.

Accordingly, the light emitting layers EL may not emit light in portions overlapping the anode contact holes ACTH or the third pixel defining layer PDL3, and the portions overlapping the anode contact holes ACTH or the third pixel defining layer PDL3 may be defined as the second non-emission areas NLA2.

In some embodiments, a first thickness H31 of each light emitting layer EL not overlapping an anode contact hole ACTH may be greater than a second thickness H32 of the light emitting layer EL overlapping the anode contact hole ACTH in the third direction DR3. For example, the second thickness H32 may be 30% or less of the first thickness H31. Redundant descriptions will be omitted.

The cathodes CE included in the display element layer EML may be located on the light emitting layers EL. The cathodes CE may cover the entirety of the second pixel defining layer PDL2 and the third pixel defining layer PDL3. The cathodes CE may cover the third pixel defining layer PDL3 along the shape of the third pixel defining layer PDL3 in the portions overlapping the anode contact holes ACTH. In the fabrication process, the cathodes CE may have a higher step coverage than the process of forming the light emitting layers EL. Accordingly, the cathodes CE may contact and cover the entirety of the light emitting layers EL in the portions overlapping the anode contact holes ACTH.

As described above, since the display device 10 of the embodiment includes the third pixel defining layer PDL3, it can solve a short-circuit between the anodes AE and the cathodes CE during a process.

The auxiliary electrodes AX included in the display element layer EML may be located on the light emitting layers EL. The auxiliary electrodes AX may cover the entirety of the second pixel defining layer PDL2 and the third pixel defining layer PDL3. The auxiliary electrodes AX may cover the third pixel defining layer PDL3 along the shape of the third pixel defining layer PDL3 in the portions overlapping the anode contact holes ACTH. The auxiliary electrodes AX may cover the entirety of the cathodes CE in the portions overlapping the anode contact holes ACTH. Other redundant descriptions will be omitted.

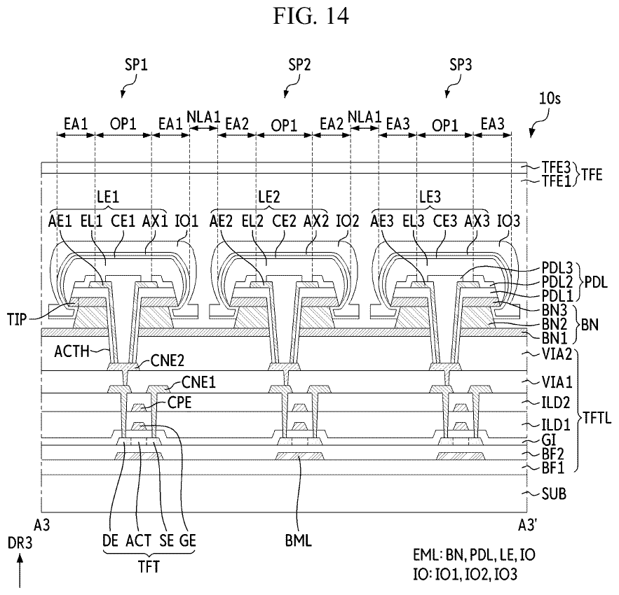

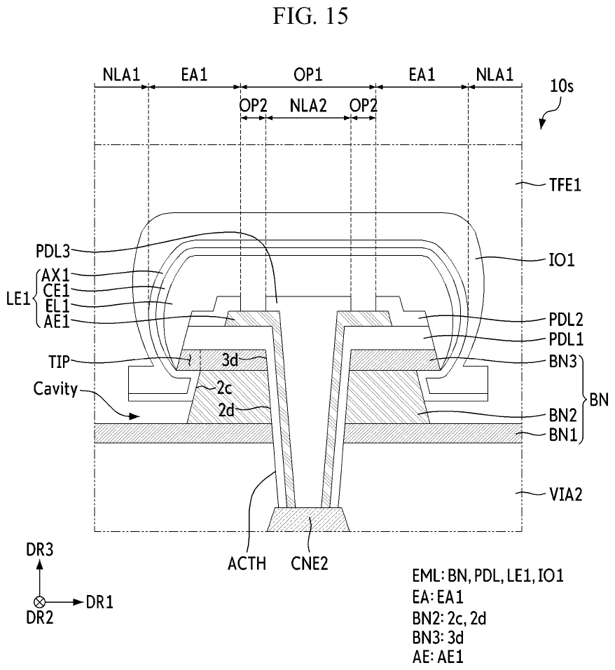

FIG. 14 is another embodiment and a cross-sectional view of an example of a display panel taken along line A3-A3′ of FIG. 7. FIG. 15 is an enlarged cross-sectional view of a display element layer EML overlapping a first emission area in FIG. 14.

Referring to FIGS. 14 and 15, the display element layer EML of a display device 10s may have a different shape from the display element layer EML of the display device 10 because a third pixel defining layer PDL3 includes an organic material. A description of the common structure of the display device 10 and the display device 10s will be omitted, and differences will be described below.

The third pixel defining layer PDL3 included in the display device 10s may be located in portions overlapping emission areas EA. The third pixel defining layer PDL3 may define each second opening OP2 with a neighboring second pixel defining layer PDL2. An anode AE may be exposed in a portion overlapping each second opening OP2 and may contact a light emitting layer EL in the portion overlapping each second opening OP2.

The third pixel defining layer PDL3 included in the display device 10s may cover the entirety of the anodes AE in portions overlapping anode contact holes ACTH. In addition, the third pixel defining layer PDL3 may flatten steps formed by the anodes AE in the portions overlapping the anode contact holes ACTH.

The third pixel defining layer PDL3 included in the display device 10s may include an organic material. For example, the third pixel defining layer PDL3 may include a photosensitive material such as polyamide resin, polyimide resin, acrylic resin, epoxy resin, or phenolic resin.

In a process of fabricating the display device 10s, the third pixel defining layer PDL3 may be formed through a separate process after the second pixel defining layer PDL2 is formed.

In the display device 10s of an embodiment, since the third pixel defining layer PDL3 is formed between the anodes AE and cathodes CE in the portions overlapping the anode contact holes ACTH, it is possible to solve a short-circuit between the anodes AE and the cathodes CE and thus can solve a driving failure of the light emitting elements. Other redundant descriptions will be omitted.

Light emitting layers EL included in the display device 10s may cover the entirety of the anodes AE in the portions overlapping the anode contact holes ACTH. However, the light emitting layers EL may be spaced apart from the anodes AE with the third pixel defining layer PDL3 interposed between them in the portions overlapping the anode contact holes ACTH and may contact the anodes AE in portions not overlapping the anode contact holes ACTH.

Accordingly, the light emitting layers EL may not emit light in portions overlapping the anode contact holes ACTH, and the portions overlapping the anode contact holes ACTH may be defined as second non-emission areas NLA2.

The cathodes CE included in the display device 10s may be located on the second pixel defining layer PDL2 and the third pixel defining layer PDL3. The cathodes CE may cover the entirety of the second pixel defining layer PDL2 and the third pixel defining layer PDL3.

Auxiliary electrodes AX included in the display device 10s may be located on the second pixel defining layer PDL2 and the third pixel defining layer PDL3. The auxiliary electrodes AX may cover the entirety of the second pixel defining layer PDL2 and the third pixel defining layer PDL3. Other redundant descriptions will be omitted.

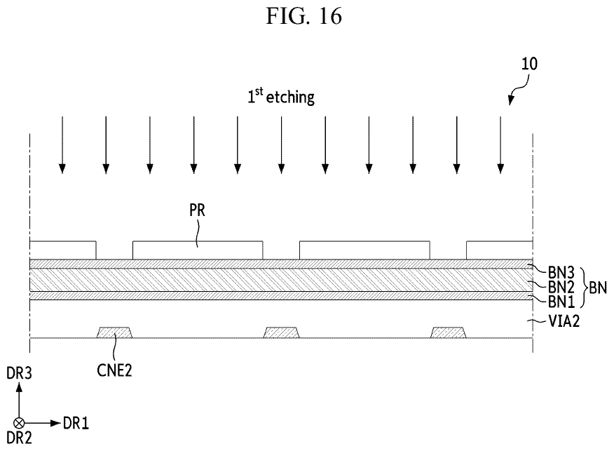

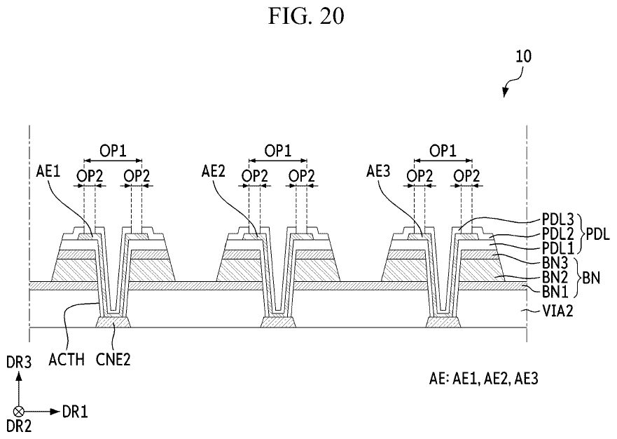

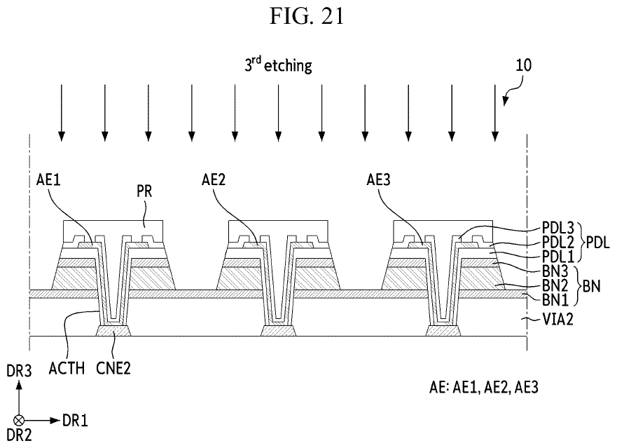

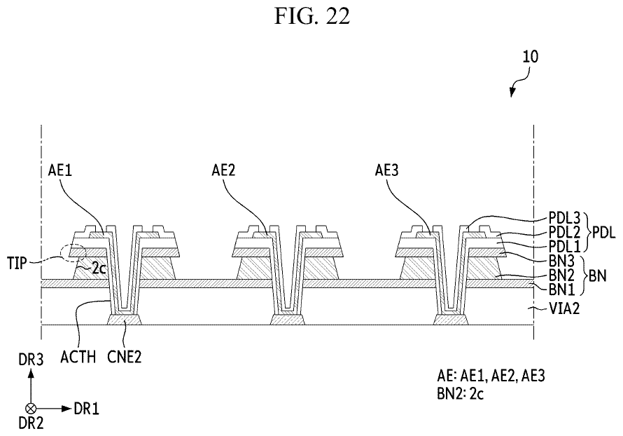

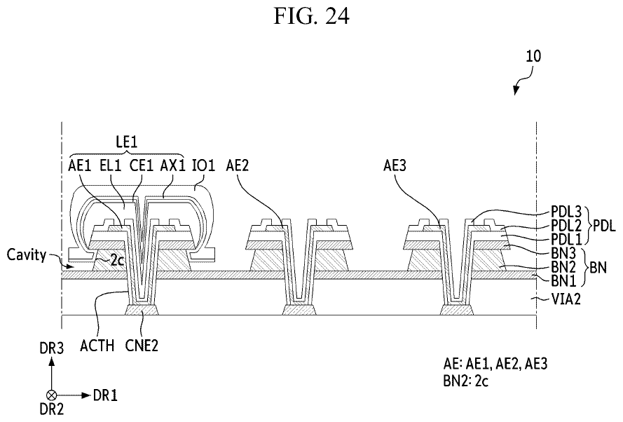

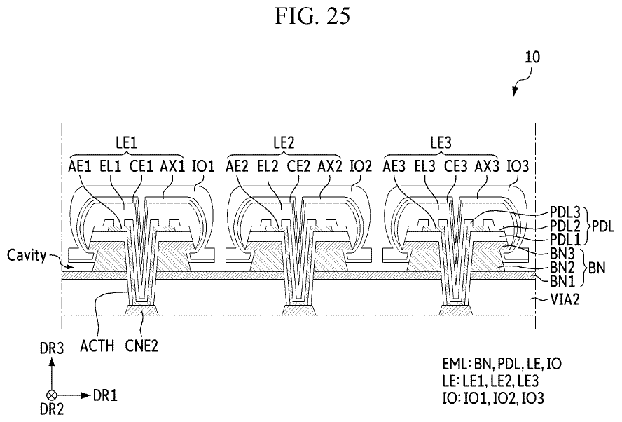

FIGS. 16 through 25 are cross-sectional views sequentially illustrating a method of fabricating the display element layer EML of FIG. 11. A process of fabricating a display element layer overlapping anode contact holes will now be described in the order of formation of each layer.

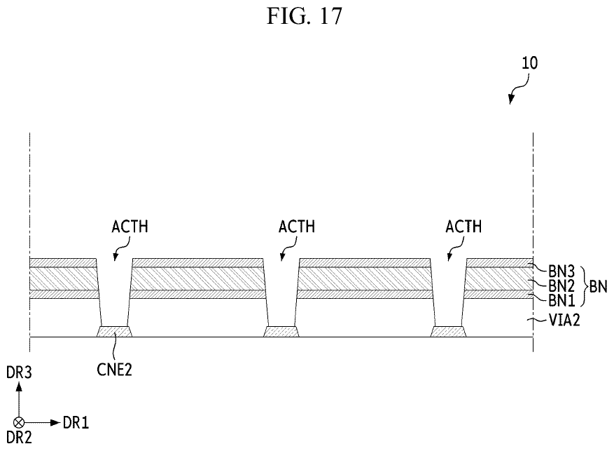

Referring to FIGS. 16 and 17, a bank structure BN is formed on a second via-layer VIA2 which covers second connection electrodes CNE2. The bank structure BN may cover the entirety of the second via-layer VIA2 and may include a first bank layer BN1, a second bank layer BN2 and a third bank layer BN3 stacked sequentially.

In the current process, the second bank layer BN2 and the third bank layer BN3 may include different materials from each other. For example, the third bank layer BN3 may include a material having etch resistance greater than etch resistance of the second bank layer BN2 in the same etching process. Redundant descriptions will be omitted.

Next, after a plurality of photoresists PR are formed on the third bank layer BN3, a first etching process is performed using the photoresists PR as a mask. For example, the first etching process may be performed as a dry etching process.

In the current process, the bank structure BN not overlapped by the photoresists PR may be removed. Accordingly, anode contact holes ACTH may be formed. Side surfaces of the second via-layer VIA2, the first bank layer BN1, the second bank layer BN2 and the third bank layer BN3 facing the anode contact hole ACTH may be located in line with each other. In the current process, the second connection electrodes CNE2 may be exposed in portions overlapping the anode contact holes ACTH. An angle formed by each second connection electrode CNE2 and each anode contact hole ACTH may vary according to embodiments.

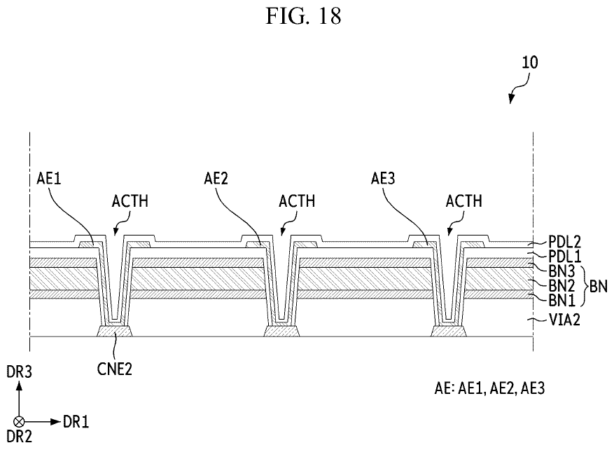

Next, referring to FIG. 18, a first pixel defining layer PDL1 is formed on the third bank layer BN3. In the current process, the first pixel defining layer PDL1 may cover the entirety of the side surfaces of the second via-layer VIA2, the first bank layer BN1, the second bank layer BN2 and the third bank layer BN3 facing the anode contact holes ACTH.

In the current process, the first pixel defining layer PDL1 may expose the second connection electrodes CNE2 in the portions overlapping the anode contact holes ACTH. For example, the first pixel defining layer PDL1 may be formed to cover the second connection electrodes CNE2, and then its portions overlapping the second connection electrodes CNE2 may be removed by a subsequent etching process. Alternatively, the first pixel defining layer PDL1 may be formed to expose the portions overlapping the second connection electrodes CNE2 using a mask.

In the current process, a first thickness of the first pixel defining layer PDL1 overlapping the anode contact holes ACTH may be smaller than a second thickness of the first pixel defining layer PDL1 not overlapping the anode contact holes ACTH in the third direction DR3. This may be caused by a change in step coverage characteristics of the process of forming the first pixel defining layer PDL1 according to the profile formed by the anode contact holes ACTH. Other descriptions are provided above in FIG. 13 and thus will be omitted.

Next, anodes AE are formed on the first pixel defining layer PDL1. A plurality of anodes AE may be formed and may contact the second connection electrodes CNE2 in the portions overlapping the anode contact holes ACTH.

The anodes AE may include a first anode AE1, a second anode AE2, and a third anode AE3. The first anode AE1, the second anode AE2, and the third anode AE3 may be spaced apart from each other.

Next, a second pixel defining layer PDL2 is formed to cover the anodes AE. The second pixel defining layer PDL2 may be formed on the entire surface and may cover the first pixel defining layer PDL1 and the anodes AE along the profile formed by the first pixel defining layer PDL1 and the anodes AE.

In the current process, a first thickness of the anodes AE overlapping the anode contact holes ACTH may be smaller than a second thickness of the anodes AE not overlapping the anode contact holes ACTH in the third direction DR3. This may be caused by a change in step coverage characteristics of the process of forming the anodes AE according to the profile formed by the anode contact holes ACTH. Other descriptions are provided above in FIG. 13 and thus will be omitted.

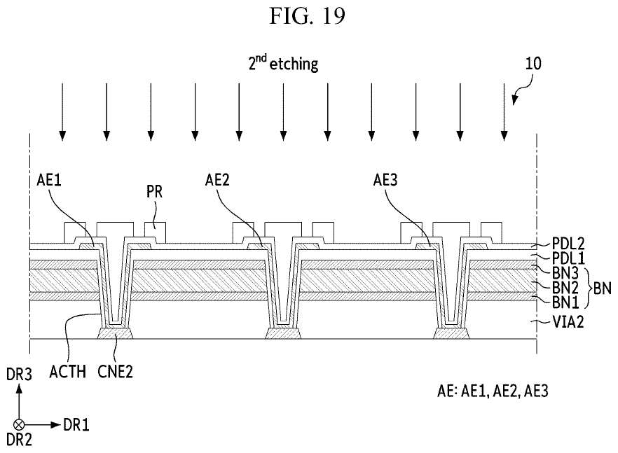

Referring to FIGS. 19 through 22, a plurality of photoresists PR are formed on the second pixel defining layer PDL2. In the current process, the photoresists PR may be formed to overlap edges of the anodes AE and the anode contact holes ACTH.

Next, a second etching process is performed using the photoresists PR as a mask. For example, the second etching process may be performed as a dry etching process.

In the current process, portions of the pixel defining layer PDL, the second bank layer BN2, and the third bank layer BN3 which are not overlapped by the photoresists PR may be removed. As a result, the pixel defining layer PDL may be formed into the first pixel defining layer PDL1, the second pixel defining layer PDL2, and a third pixel defining layer PDL3.

As described above, the first pixel defining layer PDL1 may prevent the bank structure BN and the anodes AE from contacting each other. In addition, the second pixel defining layer PDL2 may define first openings OP1 overlapping emission areas EA and may surround the edges of the anodes AE. In addition, the third pixel defining layer PDL3 may be located in the portions overlapping the anode contact holes ACTH and may define each second opening OP2 with the neighboring second pixel defining layer PDL2. An anode AE may be exposed in a portion overlapping each second opening OP2.

In the current process, the second pixel defining layer PDL2 and the third pixel defining layer PDL3 may be formed by a single process. Therefore, a display device 10 of an embodiment can be easily fabricated.

Next, after a plurality of photoresists PR are formed to cover the entirety of the second pixel defining layer PDL2 and the third pixel defining layer PDL3, a third etching process is performed. For example, the third etching process may be performed as a wet etching process.

In the current process, the second bank layer BN2 and the third bank layer BN3 including different metal materials may have different etch rates. Specifically, the third bank layer BN3 may have higher etch resistance than the second bank layer BN2 in the same etching process. In other words, the second bank layer BN2 may include a material having a higher etch rate than an etch rate of the third bank layer BN3 in the same etching process. Therefore, the third bank layer BN3 may include tips TIP that protrude more than first side surfaces 2c of the second bank layer BN2 in the first direction DR1.

In the current process, the first pixel defining layer PDL1 and the second pixel defining layer PDL2 may overlap the tips TIP of the third bank layer BN3 in the third direction DR3.

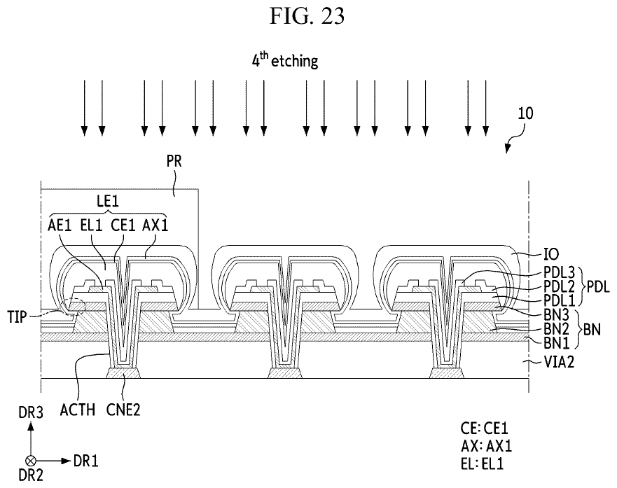

Next, referring to FIGS. 23 through 25, a first light emitting layer EL1, a first cathode CE1, and a first auxiliary electrode AX1 are deposited on the first anode AE1 to form a first light emitting element LE1.

In the current process, a process of forming the first light emitting layer EL1 may be performed through a thermal deposition process. In the current process, a material that forms the first light emitting layer EL1 may be formed not only on the first anode AE1, but also on the second anode AE2, the third anode AE3, and the first bank layer BN1.

In the display device 10 of the embodiment, since the third bank layer BN3 includes the tips TP, the material that forms the first light emitting layer EL1 formed on the first anode AE1 may be spaced apart from the material that forms the first light emitting layer EL1 formed on the second anode AE2, the third anode AE3 and the first bank layer BN1. In other words, in the display device 10, since the third bank layer BN3 includes the tips TIP, light emitting layers EL spaced apart from each other can be formed on the first anode AE1, the second anode AE2 and the third anode AE3, respectively, without using a fine metal mask.

In the current process, a process of forming the first cathode CE1 may be performed through a thermal deposition process or a sputtering process. The process of forming the first cathode CE1 may have higher step coverage characteristics than the process of forming the first light emitting layer EL1. Therefore, the first cathode CE1 may cover the entirety of the first light emitting layer EL1.

In the current process, a material that forms the first cathode CE1 may be formed not only on the first anode AE1, but also on the second anode AE2, the third anode AE3, and the first bank layer BN1.

In the display device 10 of the embodiment, since the third bank layer BN3 includes the tips TIP, the material that forms the first cathode CE1 formed on the first anode AE1 may be spaced apart from the material that forms the first cathode CE1 formed on the second anode AE2, the third anode AE3 and the first bank layer BN1. In other words, in the display device 10, since the third bank layer BN3 includes the tips TIP, cathodes CE spaced apart from each other can be formed on the first anode AE1, the second anode AE2 and the third anode AE3, respectively, without using a fine metal mask.

In the current process, a process of forming the first auxiliary electrode AX1 may be performed through a sputtering process. The process of forming the first auxiliary electrode AX1 may have higher step coverage characteristics than the process of forming the first cathode CE1. Therefore, the first auxiliary electrode AX1 may cover the entirety of the first cathode CE1.

In the current process, a material that forms the first auxiliary electrode AX1 may be formed not only on the first anode AE1, but also on the second anode AE2, the third anode AE3, and the first bank layer BN1.

In the display device 10 of the embodiment, since the third bank layer BN3 includes the tips TIP, the material that forms the first auxiliary electrode AX1 formed on the first anode AE1 may be spaced apart from the material that forms the first auxiliary electrode AX1 formed on the second anode AE2, the third anode AE3 and the first bank layer BN1. In other words, in the display device 10, since the third bank layer BN3 includes the tips TIP, auxiliary electrodes AX spaced apart from each other can be formed on the first anode AE1, the second anode AE2 and the third anode AE3, respectively, without using a fine metal mask.

Next, an element inorganic layer IO is formed on the first auxiliary electrode AX1. The element inorganic layer IO may cover a structure thereunder with a uniform thickness along the profile of the structure thereunder.

Next, a photoresist PR is formed in a portion overlapping the first anode AE1 and an area around the first anode AE1, and a fourth etching process is performed using the photoresist PR as a mask.

In the current process, the material that forms the first light emitting layer EL1, the material that forms the first cathode CE1, the material that forms the first auxiliary electrode AX1, and a material that forms the element inorganic layer IO in a portion not overlapping the photoresist PR may all be removed at once. Through this process, the second anode AE2 and the third anode AE3 may be exposed again, and the material that forms the element inorganic layer IO may be formed into a first element inorganic layer IO1.

In the current process, since the display device 10 of the embodiment includes the third pixel defining layer PDL3 in the portions overlapping the anode contact holes ACTH, it is possible to solve a short-circuit between the anodes AE and the cathodes CE. Redundant descriptions will be omitted.

In the current process, cavities Cavity may be formed between the first element inorganic layer IO1 and the first bank layer BN1 in the third direction DR3. In other words, the cavities Cavity may be formed between the first auxiliary electrode AX1 and the first bank layer BN1 in the third direction DR3. The cavities Cavity may be formed by removal of the material that forms the first light emitting layer EL1 and the material that forms the first cathode CE1 which were temporarily located on the first bank layer BN1.

In the current process, the first auxiliary electrode AX1 may contact and cover the first side surfaces 2c of the second bank layer BN2. Accordingly, the first cathode CE1 may be electrically connected to the second bank layer BN2 through the first auxiliary electrode AX1. As described above, the second bank layer BN2 may be electrically connected to the first bank layer BN1.

Next, the same process is repeated to form a second light emitting layer EL2, a second cathode CE2, and a second auxiliary electrode AX2 on the second anode AE2. Accordingly, a second light emitting element ED2 and a second element inorganic layer IO2 are formed. In addition, a third light emitting layer EL3, a third cathode CE3, and a third auxiliary electrode AX3 are formed on the third anode AE3 to form a third light emitting element ED3 and a third element inorganic layer IO3. As a result, the light emitting element layer EML overlapping the anode contact holes ACTH illustrated in FIG. 11 may be formed. Redundant descriptions will be omitted.

The display device according to one embodiment of the present disclosure can be applied to various electronic devices. The electronic device according to the one embodiment of the present disclosure includes the display device described above, and may further include modules or devices having additional functions in addition to the display device.

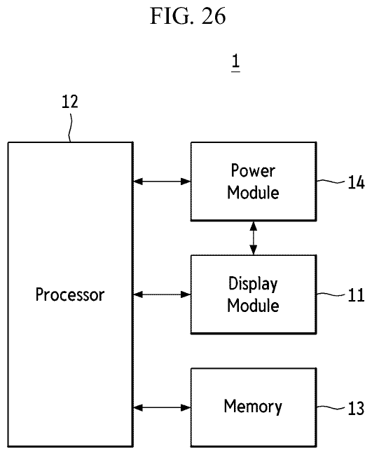

FIG. 26 is a block diagram of an electronic device according to one embodiment of the present disclosure.

Referring to FIG. 26, the electronic device 1 according to one embodiment of the present disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information necessary for the operation of the processor 12 or the display module 11. When the processor 12 executes an application stored in the memory 13, an image data signal and/or an input control signal is transmitted to the display module 11, and the display module 11 can process the received signal and output image information through a display screen.

The power module 14 may include a power supply module such as, for example a power adapter or a battery, and a power conversion module that converts the power supplied by the power supply module to generate power necessary for the operation of the electronic device 1.

At least one of the components of the electronic device 11 according to the one embodiment of the present disclosure may be included in the display device 10 according to the embodiments of the present disclosure. In addition, some modules of the individual modules functionally included in one module may be included in the display device 10, and other modules may be provided separately from the display device 10. For example, the display device 10 may include the display module 11, and the processor 12, the memory 13, and the power module 14 may be provided in the form of other devices within the electronic device 11 other than the display device 10.

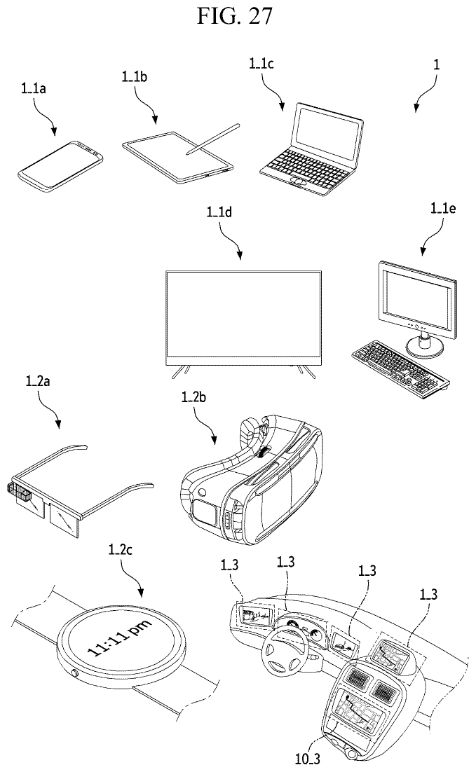

FIG. 27 is a schematic diagram of an electronic device according to various embodiments of the present disclosure.

Referring to FIG. 27, various electronic devices to which display devices 10 according to embodiments of the present disclosure are applied may include not only image display electronic devices such as a smart phone 10_1a, a tablet PC (personal computer) 10_1b, a laptop 10_1c, a TV 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a CID (Center Information Display) and a room mirror display arranged on a dashboard, center fascia, and dashboard of an automobile.

According to a display device and a method of fabricating the same according to embodiments, it is possible to provide a high-resolution image and solve a short-circuit between an anode and a cathode.

However, the effects of the present disclosure are not restricted to the one set forth herein. The above and other effects of the present disclosure will become more apparent to one of daily skill in the art to which the present disclosure pertains by referencing the claims.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate comprising an emission area and a non-emission area surrounding the emission area;
a bank structure located on the emission area of the substrate and comprising a tip protruding toward the non-emission area;
an anode contact hole penetrating the bank structure;
an anode located on the bank structure and electrically connected to a transistor located on the substrate through the anode contact hole;
a pixel defining layer located on the anode; and
a light emitting layer located on the pixel defining layer,
wherein the light emitting layer is spaced apart from the anode with the pixel defining layer therebetween in a portion overlapping the anode contact hole in a plan view and contacts the anode in a portion not overlapping the anode contact hole in the plan view.

2. The display device of claim 1, wherein the bank structure comprises:
a first bank layer;
a second bank layer located on the first bank layer; and
a third bank layer having the tip, which protrudes toward the non-emission area more than a first side surface of the second bank layer which faces the non-emission area.

3. The display device of claim 2, wherein the second bank layer and the third bank layer surround the anode contact hole.

4. The display device of claim 3, wherein a shape of the bank structure facing the anode contact hole and a shape of the bank structure facing the non-emission area are different from each other.

5. The display device of claim 4, wherein a second side surface of the second bank layer is in line with a third side surface of the third bank layer which face the anode contact hole.

6. The display device of claim 2, wherein the pixel defining layer comprises:
a first pixel defining layer located between the bank structure and the anode;
a second pixel defining layer covering an edge of the anode and overlapping the emission area to define a first opening; and
a third pixel defining layer overlapping the anode contact hole and located under the light emitting layer and on the anode.

7. The display device of claim 6, wherein a second opening is defined between the third pixel defining layer and the second pixel defining layer in a direction parallel to a major surface of the substrate.

8. The display device of claim 7, wherein the light emitting layer contacts the anode in a portion overlapping the second opening in the plan view.

9. The display device of claim 6, wherein the first pixel defining layer and the second pixel defining layer overlap the tip of the third bank layer in a direction perpendicular to a major surface of the substrate.

10. The display device of claim 6, wherein the second pixel defining layer and the third pixel defining layer comprise a same material.

11. The display device of claim 2, further comprising:
a first cathode located on the light emitting layer;
a first auxiliary electrode located on the first cathode and contacting the first side surface of the second bank layer; and
a first element inorganic layer located on the first auxiliary electrode.

12. The display device of claim 11, wherein the first cathode does not contact the first side surface of the second bank layer and is electrically connected to the second bank layer through the first auxiliary electrode.

13. The display device of claim 11, wherein the first auxiliary electrode is spaced apart from the first bank layer with a cavity therebetween in the direction perpendicular to a major surface of the substrate.

14. The display device of claim 11, further comprising:
a second cathode spaced apart from the first cathode in a portion overlapping the non-emission area;
a second auxiliary electrode located on the second cathode and spaced apart from the first auxiliary electrode; and
a second element inorganic layer located on the second auxiliary electrode and spaced apart from the first element inorganic layer,
wherein the first auxiliary electrode and the second auxiliary electrode are electrically connected.

15. The display device of claim 1, further comprising:
a connection electrode located between the substrate and the bank structure and electrically connected to the transistor; and
a via-layer covering the connection electrode,
wherein the anode contact hole penetrates the via-layer, and the anode is electrically connected to the transistor through the connection electrode.

16. The display device of claim 6, wherein the second pixel defining layer comprises an inorganic material, and the third pixel defining layer comprises an organic material.

17. A method of fabricating a display device, the method comprising:
forming a bank structure having an undercut shape on an emission area of the substrate;
forming an anode contact hole which penetrates the bank structure and exposes a connection electrode;
forming an anode which is located on the bank structure and contacts the connection electrode through the anode contact hole; and
forming a pixel defining layer on the anode and forming a light emitting layer and a cathode on the pixel defining layer,
wherein the anode and the light emitting layer are separated by the pixel defining layer in a portion overlapping the anode contact hole.

18. The method of claim 17, wherein the bank structure comprises a first bank layer, a second bank layer and a third bank layer, the second bank layer and the third bank layer comprise different metal materials from each other, and in the forming of the anode contact hole, the anode contact hole is formed by simultaneously removing a portion of each of the first bank layer, the second bank layer and the third bank layer.

19. The method of claim 18, wherein in the forming of the light emitting layer and the cathode, the light emitting layer and the cathode are formed by a deposition process and an etching process without a fine metal mask.

20. An electronic device comprising:
at least one display device comprising a substrate which comprises an emission area and a non-emission area;
a display device housing in which the at least one display device is accommodated; and
an optical member configured to enlarge an image displayed by the at least one display device or convert an optical path,
wherein the at least one display device comprises:
a bank structure located on the emission area of the substrate and comprising a tip protruding toward the non-emission area;
an anode contact hole penetrating the bank structure;
an anode located on the bank structure and electrically connected to a transistor located on the substrate through the anode contact hole;
a pixel defining layer located on the anode; and
a light emitting layer located on the pixel defining layer,
wherein the light emitting layer is spaced apart from the anode with the pixel defining layer therebetween in a portion overlapping the anode contact hole in a plan view and contacts the anode in a portion not overlapping the anode contact hole in the plan view.
